(19) United States
(12) Patent Application Publication
(10) Pub. No.: US 2004/0229390 A1
(43) Pub. Date: Nov. 18, 2004

(54) Method for manufacturing of light emitting device with composed chemical semiconductor

(76) Inventor: Jung Hoon Seo, Seoul (KR)

Correspondence Address: BIRCH STEWART KOLASCH & BIRCH, PO BOX 747, FALLS CHURCH, VA, 22040-0747, US

(21) Appl. No.: 10/791,813

(22) Filed: Mar. 4, 2004

(30) Foreign Application Priority Data
Mar. 7, 2003 (KR) 10-2003-0014381

(51) Int. Cl. H01L 21/00

(52) U.S. Cl. 438/22

(57) ABSTRACT

The present invention relates to a method for manufacturing light-emitting device with compound semiconductor and more particularly, a method for manufacturing light-emitting device with Group III-V compound semiconductor for increasing light-emitting efficiency or long durability of elements, by conducting of a heat-treatment at lower temperature than done at the conventional art, i.e. activating p-semiconductor layer under the condition of high oxygen density, which idea is derived from the well known fact that on the higher oxygen density, the better semiconductor layer doped with p-type such like p-GaN can be activated.

The present invention is a method for manufacturing light-emitting device with compound semiconductor comprising; a first step of forming n-semiconductor layer, an activated layer, a p-semiconductor layer in order on the top of a double substrate, a second step of making a part of the n-semiconductor with that mesa-cut in vertical direction from a p-semiconductor layer to a part of the n-semiconductor, a third step of forming a transparent electrode for extending an electric current on the top of the p-semiconductor layer and activating the p-semiconductor layer under the condition of an oxygen plasma, and a fourth step of forming each of the n-pad electrode and the p-pad electrode on the top of the transparent electrode for extending an electric current.

This Nonprovisional application claims priority under 35 U.S.C. § 119(a) on Patent Application No. 10-2003-0014381 filed in Korea on Mar. 7, 2003, the entire contents of which are hereby incorporated by reference.

### BACKGROUND OF THE INVENTION

1. Field of the Invention

The present invention relates to a method for manufacturing light-emitting device with compound semiconductor and more particularly, a method for manufacturing light-emitting device with Group III-V compound semiconductor for increasing light-emitting efficiency or long durability of elements, by conducting of a heat-treatment at lower temperature than done at the conventional art, i.e. activating p-semiconductor layer under the condition of high oxygen density, which idea is derived from the well known fact that on the higher oxygen density, the better semiconductor layer doped with p-type such like p-GaN can be activated.

2. Description of the Background Art

Generally, The Group III-V compound semiconductor as a kind of a direct transition type, has high light-emitting efficiency so the semiconductor is used very widely for light-emitting elements such like diode elements (laser diode elements), photodetectors (solar battery, optical sensors), electronic devices (transistor, power device) and so on.

A method for manufacturing of said Group III-V compound semiconductor has three methods which are MBE (Molecular Beam Epitaxy), MOVPE (Metal Organic Vapor Phase Epitaxy), and HVPE (Hydride Vapor Phase Epitaxy).

Particularly, MOVPE method has been used widely as a method for manufacturing a Group III-V compound semiconductor because it can achieve an uniformed Group III-V compound semiconductor with and high quality. FIG. 1 shows a light-emitting element manufactured following the conventional art of MOVPE.

As shown in FIG. 1, the conventional light-emitting elements of Group III-V compound semiconductor has a Gallium-Niride layer (n-GaN)(11) doped with n-type on the top of a sapphire substrate and an activated layer is formed thereon. The p-GaN doped with p-type (13) is formed on the activated layer and a part of the n-GaN layer (11) become to be exposed and the n-pad electrode (15) is formed thereon, a transparent electrode (14) and the p-pad electrode (16) for extending an electric current is formed in sequency on the top of said p-GaN layer (13).

The said Group III-V compound semiconductor formed as above, especially the p-GaN layer 13 is conducting of a heat-treatment under the condition of Nitrogen and Oxygen at conventional art because it have to be formed with a high hole concentration.

For example, if the p-GaN doped with p-type with Magnesium is formed by MOCVD method, magnesium accepter cannot be activated but combined to a hydrogen so that a neutrality complex, Mg—H is formed by. In order to prevent the said matter, high heat treatment make Mg—H's bonding cut and then it makes Hydrogen which was combined to magnesium will be out.

However, high-temperature treatment needs lots of thermal energy. Also it occurred several problems such as a deterioration and a deformation of the said Group III-V compound semiconductor so the durability and light-emitting efficiency of the light-emitting elements is decreased.

### SUMMARY OF THE INVENTION

The object of the present invention is to provide a method for manufacturing light-emitting device with compound semiconductor in order to solve the above problems.

The present invention is a method for manufacturing light-emitting device with compound semiconductor comprising; a first step of forming n-semiconductor layer, an activated layer, a p-semiconductor layer in order on the top of a double substrate, a second step of making a part of the n-semiconductor with that mesa-cut in vertical direction from a p-semiconductor layer to a part of the n-semiconductor, a third step of forming a transparent electrode for extending an electric current on the top of the p-semiconductor layer and activating the p-semiconductor layer under the condition of an oxygen plasma, and a fourth step of forming each of the n-pad electrode and the p-pad electrode on the top of the transparent electrode for extending an electric current.

Said double substrate is preferably a sapphire substrate. Also, it is prefer that the p-semiconductor and the n-semiconductor layer is a Group III-V compound semiconductor, especially a GaN layer.

### BRIEF DESCRIPTION OF THE DRAWINGS

The invention will be described in detail with reference to the following drawings in which like numerals refer to like elements.

FIG. 1 shows a light-emitting element manufactured following the conventional art of MOVPE.

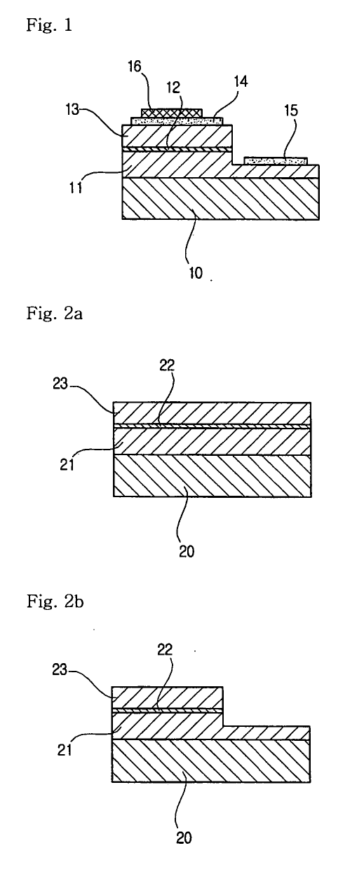

FIG. 2a to FIG. 2e show the sequence of Preferred embodiments.

### DETAILED DESCRIPTION OF PREFERRED EMBODIMENTS

Preferred embodiments of the present invention will be described in a more detailed manner with reference to the drawings.

The present invention is a method for manufacturing light-emitting device with compound semiconductor comprising; a first step of forming n-semiconductor layer, an activated layer, a p-semiconductor layer in order on the top of a double substrate, a second step of making a part of the n-semiconductor with that mesa-cut in vertical direction from a p-semiconductor layer to a part of the n-semiconductor, a third step of forming a transparent electrode for extending an electric current on the top of the p-semiconductor layer and activating the p-semiconductor layer under the condition of an oxygen plasma, and a fourth step of forming each of the n-pad electrode and the p-pad electrode on the top of the transparent electrode for extending an electric current.

First of all, a method for manufacturing light-emitting device with compound semiconductor according to the present invention, is to be grown Epi as forming n-type compound semiconductor layer (n-semiconductor layer), an activated layer, a p-type compound semiconductor layer (p-semiconductor layer) in order on the top of the double substrate by using of a method of MOVPE growth.

And then, a part of the n-semiconductor layer is made exposed by mesa-cut in vertical direction of semiconductor which is from the p-semiconductor to the part of the n-semiconductor.

After that, a transparent electrode for extending electric current which is made by a metal material is formed on the top of said p-semiconductor layer and, conduct of the heat-treatment for the p-semiconductor layer's activation at the same time when a p-semiconductor layer omic-connect to the transparent electrode.

At that time, based on the fact that the p-semiconductor layer can be activated more under the condition of the higher O2 density, the p-semiconductor layer is activated under the condition of Oxygen plasma Ion not like the conventional art instead of Oxygen molecule or Nitrogen molecule.

Accordingly, if the p-semiconductor is activated under the condition of Oxygen or Nitrogen Molecule, H2 can be out under the condition of molecule as to be separated from the used material when p-semiconductor layer is grown.

And, it was necessary lots of energy because it have to conduct of the heat-treatment at 600° C. instead H2O and H2 of being out easily after changed O2 to Oxygen Ion.

So, if maintaining the condition of Oxygen at low temperature, H2O can be out easily and unnecessary energy cannot be wasted.

If the p-semiconductor layer be activated under the condition of O2 plasma according to the present invention, the p-semiconductor layer can be activated better comparing with the conventional art which makes it activated at high temperature, and it can be saved the unnecessary thermal energy waste.

After the p-semiconductor layer is activated through the heat-treatment, a n-pad electrode is formed on the top of the n-semiconductor layer for a wire bonding and a p-pad electrode is formed on the top of the transparent electrode.

Accordingly, as to be activated a p-semiconductor layer under the condition of the oxygen plasma at low temperature comparing with the conventional art, a durability or an efficiency of the light-emitting element can be increased.

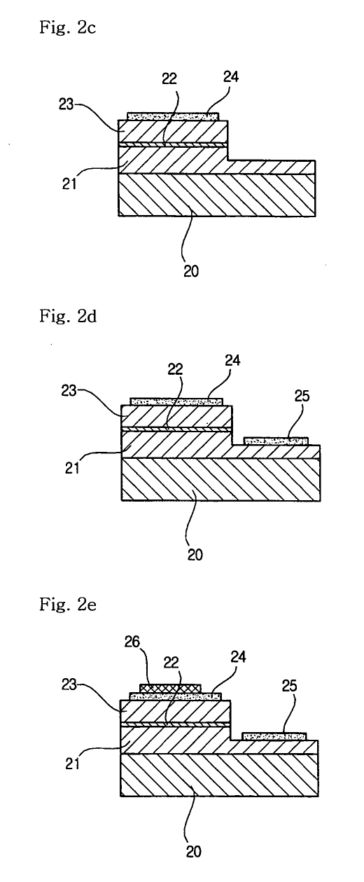

FIG. 2a to FIG. 2e show the sequence of Preferred embodiments.

At the preferred embodiment, a semiconductor layer is described as Group III-V compound semiconductor layer, especially a n-semiconductor described “n-GaN”, a p-semiconductor described “p-GaN”, and a double substrate described sapphire substrate.

First of all, FIG. 2a shows the growth of n-GaN 21, an activated layer 22, p-GaN 23 on the top of a sapphire substrate 20 as followed of the method of MOVPE growth.

And then, a part of the n-semiconductor layer 23 is made exposed by mesa-cut in vertical direction of from the p-semiconductor to the part of the n-semiconductor as described FIG. 2b, and a transparent electrode 24 for extending electric current which is made by a metal material is formed on the top of said p-semiconductor layer 23 as described FIG. 2c.

After that, it conducted of the heat-treatment at the same time when the p-semiconductor layer 23 omic-connect to the transparent electrode for the p-semiconductor layer's activation.

At that time, it occurs high resistance because a p-type douse's acceptor such like magnesium acceptor is combined with Hydrogen. So in order to cut the above bonding in the present invention, it conducts of the heat-treatment under the condition of oxygen.

In the result, it is possible to conduct of the heat-treatment at low temperature comparing with the conventional thermal temperature 600° C. and Hydrogen broken from acceptor can be out as the form of H2O bonding with Oxygen.

When the above-said procedure is finished, n-pad electrode 25 is formed on the top of the said exposed n-GaN 21 as described FIGS. 2d and p-pad electrode 26 is formed on the top of the transparent electrode 24 as described FIG. 2e.

As described hereinabove, according to the present invention, it is possible to reduce unnecessary thermal energy waste because it can be activated at low temperature as p-semiconductor can be activated under the condition of Oxygen. And it has an effect to increase of a durability and an efficiency of the light-emitting element because p-semiconductor layer can be activated better.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method for manufacturing light-emitting device with compound semiconductor comprising; a first step of forming n-semiconductor layer, an activated layer, and p-semiconductor layer, in order, on the top of a double substrate,
a second step of making at least a part of the n-semiconductor exposed by mesa-cut in vertical direction from a p-semiconductor layer to a part of the n-semiconductor,
a third step of forming a transparent electrode for extending an electric current on the top of the p-semiconductor layer and activating the p-semiconductor layer under the condition of an oxygen plasma, and
a fourth step of forming each of n-pad electrode and p-pad electrode on the top of the transparent electrode for extending an electric current.

2. The method for manufacturing light-emitting device with compound semiconductor of claim 1, wherein said double substrate is a sapphire substrate.

3. The method for manufacturing light-emitting device with compound semiconductor of claim 1, wherein one or more of the said n-semiconductor and p-semiconductor layer is Group III-V compound semiconductor layer.
